(19) United States
(12) Patent Application Publication
(10) Pub. No.: US 2014/0183039 A1
(43) Pub. Date: Jul. 3, 2014

(54) MAGNETRON SPUTTERING DEVICE

(71) Applicants: FIH (Hong Kong) Limited, Kowloon (HK); SHENZHEN FUTAIHONG PRECISION INDUSTRY CO., LTD., Shenzhen (CN)

(72) Inventor: CHUN-JIE ZHANG, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/949,917

(22) Filed: Jul. 24, 2013

(30) Foreign Application Priority Data
Dec. 29, 2012 (CN) 2012105885337

(51) Int. Cl. C23C 14/35

(52) U.S. Cl. CPC C23C 14/35
USPC 204/298.11

(57) ABSTRACT

A magnetron sputtering device includes a vacuum chamber body defining a vacuum chamber, at least one magnetron target positioned in the vacuum chamber, and at least one shielding assembly. The at least one shielding assembly corresponds to the magnetron target. The shielding assembly includes two shielding covers positioned at two opposite sides of the magnetron target.

### BACKGROUND

1. Technical Field

The present disclosure relates to a magnetron sputtering device.

2. Description of Related Art

A magnetron sputtering device may have a shielding plate mounted between a magnetron target and a workpiece to shield portions of the workpiece, such that the shielded portions of the workpiece are not deposited with coatings. However, since the shielding plate does not directly cover/contact the workpiece, sputtered particles (atoms/ions) of the target can deposit partially on the shielded portions of the workpiece.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a schematic view of an exemplary embodiment of a magnetron sputtering device.

FIG. 2 is an enlarged view of section II shown in FIG. 1.

### DETAILED DESCRIPTION

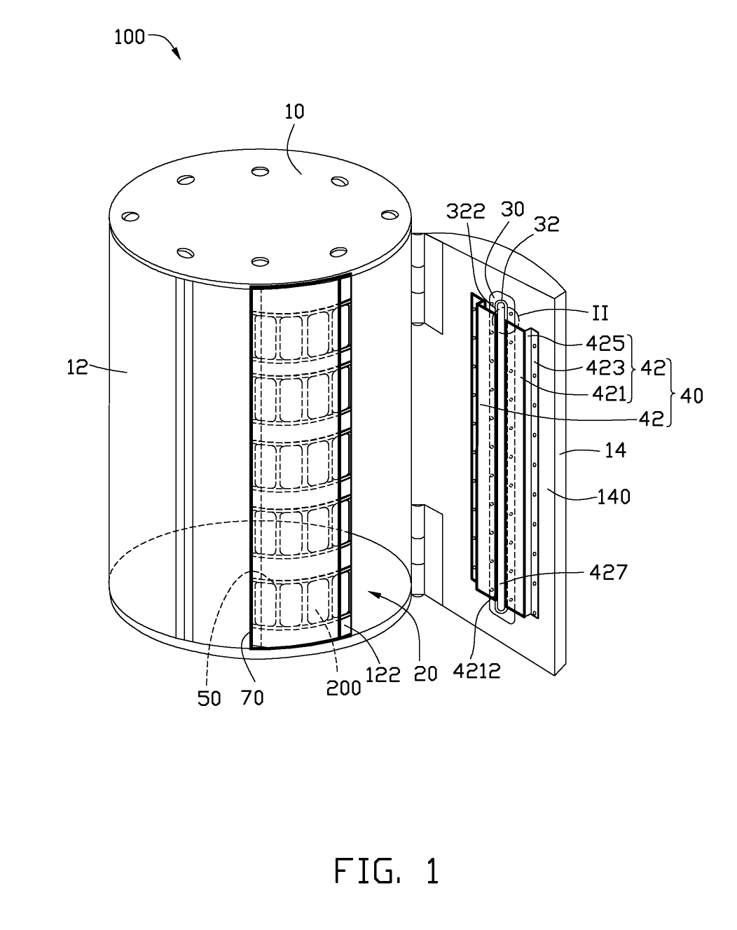

FIG. 1 shows an exemplary embodiment of a magnetron sputtering device 100, which includes a vacuum chamber body 10, a vacuum chamber 20 defined by the vacuum chamber body 10, at least one magnetron target 30 positioned in the vacuum chamber 20, and at least one shielding assembly 40 corresponding to the magnetron target 30.

The vacuum chamber body 10 includes a sidewall 12 and a door 14. The door 14 is rotatably connected to the vacuum body 10 by a pivot or a hinge. A rotating bracket 50 is positioned in the vacuum chamber 20 and a shielding plate 70 is mounted between the rotating bracket 50 and the vacuum chamber body 10. The rotating bracket 50 fixes workpiece(s) 200 in columns, and causes the workpiece(s) 200 to rotate along with the rotating bracket 50. The sidewall 12 defines an opening 122. The shielding plate 70 partially blocks the opening 122 to form a depositing opening, such that desired portions of workpieces arranged in a column face the depositing opening to allow particles sputtered by the magnetron target 30 to deposit on the workpieces 200. During sputtering, the rotating bracket 50 does not rotate.

The at least one magnetron target 30 is installed on the sidewall 12 or the door 14. In the exemplary embodiment, the magnetron sputtering device 100 includes one magnetron target 30 installed on an inner surface 140 of the door 14 facing the vacuum chamber 20. The magnetron target 30 is a substantially flat rectangular target defining an annular or U-shaped sputtering region 32. During sputtering, the sputtering region 32 is struck and etched by sputtering gas. The sputtering region 32 includes two parallel areas 322 substantially parallel to each other.

The at least one shielding assembly 40 prevents sputtering particles from depositing on undesired depositing portions of the workpieces 200. The shielding assembly 40 includes two shielding covers 42 positioned at two opposite sides of the magnetron target 30. Each shielding cover 42 includes a shielding sheet 421, a limiting sheet 423, and a connecting sheet 425 connected substantially perpendicularly between the shielding sheet 421 and the limiting sheet 423. In the exemplary embodiment, the shielding portion 421, the positioning portion 423, and the connecting portion 425 are substantially rectangular.

The shielding sheet 421 prevents low-energy particles sputtered by the magnetron target 30 from scattering and depositing on the undesired portions of the workpieces 200. The shielding sheet 421 perpendicularly extends from one lateral side of the connecting sheet 425, and the limiting sheet 423 perpendicularly extends from the opposite lateral side of the connecting sheet 425. The two shielding covers 42 are mounted substantially symmetrically on opposite sides of the magnetron target 30, and the two shielding sheets 421 are parallelly mounted on opposite sides of the magnetron target 30

Each limiting sheet 423 is secured to the inner surface 140 of the door 14. Each shielding sheet 421 is secured over the magnetron target 30 and defines a space of about 2.5 centimeters (cm) to about 3.5 cm between the shielding sheet 421 and the magnetron target 30. In the exemplary embodiment, the space between the shielding sheet 421 and the magnetron target 30 is about 3 cm. Each shielding sheet 421 has an edge 4212 located away from the connecting sheet 425. An orthographic projection of each edge 4212 is located in a corresponding parallel area 322.

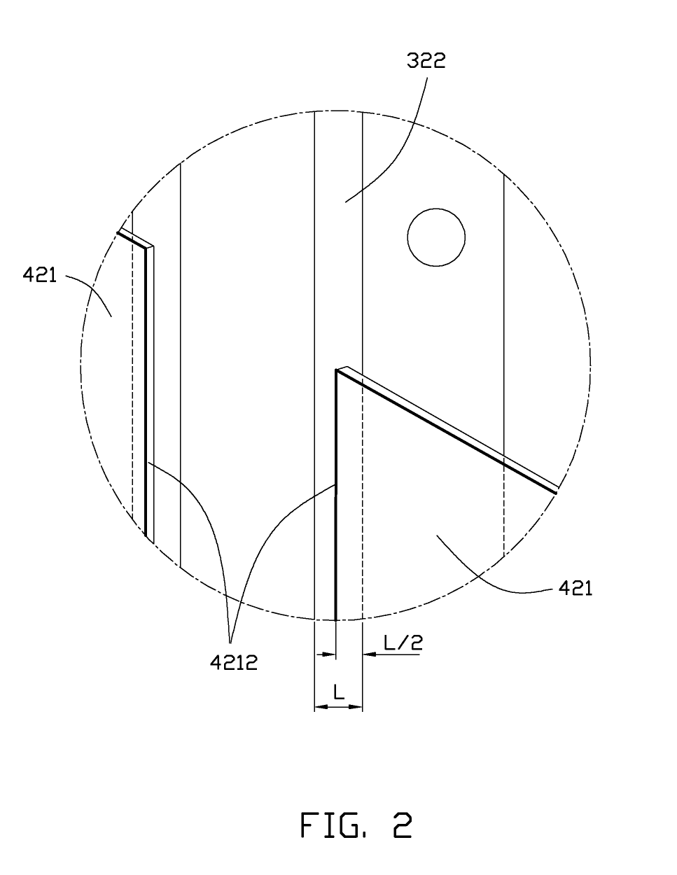

In the exemplary embodiment, the orthographic projection of each edge 4212 is located on the centerline of the corresponding parallel area 322 (see FIG. 2). The two shielding sheets 421 cooperatively define a space 427 located therebetween, allowing the sputtering particles having a highest energy to pass through the space 427 and deposit on the surfaces of the workpieces 200.

In use, the magnetron target 30 is turned on, and particles sputtered by the magnetron target 30 are deposited on the column of workpieces 200 facing the depositing openings. After deposition, the magnetron target 30 is turned off, the rotating bracket 50 rotates by a motor to make an adjacent column of workpieces 200 face the depositing openings, and the magnetron target 30 is turned on again to deposit coatings on the adjacent column of workpieces 200. In this way, as the rotating bracket 50 rotates, the workpiece(s) 200 are deposited with coatings in succession. During sputtering, because only the high-energy particles sputtered by the target 30 pass by the shielding covers 42, the particles shoot straight onto the exposed portions of the workpieces 200, and the shielding covers 42 prevent about 80% of low-energy particles sputtered by the magnetron target 30 from scattering through a space between the shielding plate 70 and the workpieces 200 and depositing on the undesired portions of the workpieces 200.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A magnetron sputtering device, comprising:
a vacuum chamber body defining a vacuum chamber therein;
at least one magnetron target positioned in the vacuum chamber; and
at least one shielding assembly corresponding to the at least one magnetron target, the shielding assembly comprising two shielding covers positioned at two opposite sides of the magnetron target.

2. The magnetron sputtering device of claim 1, further comprising a rotating bracket positioned in the vacuum chamber and a shielding plate mounted between the rotating bracket and the vacuum chamber body.

3. The magnetron sputtering device of claim 1, wherein the vacuum chamber body comprises a sidewall and a door, the door is rotatably connected to the sidewall, the least one magnetron target is installed on the sidewall or the door.

4. The magnetron sputtering device of claim 1, wherein the vacuum chamber body comprises a door rotatably connected with the vacuum chamber body, the magnetron target is installed on an inner surface of the door facing the vacuum chamber.

5. The magnetron sputtering device of claim 1, wherein the magnetron target defines a sputtering region, the sputtering region comprises two parallel areas substantially parallel to each other.

6. The magnetron sputtering device of claim 1, wherein the magnetron target is a substantially rectangular flat target including an annular or U-shaped sputtering region.

7. The magnetron sputtering device of claim 1, wherein each shielding cover comprises a shielding sheet, a limiting sheet, and a connecting sheet connected perpendicularly between the shielding sheet and the limiting sheet.

8. The magnetron sputtering device of claim 7, wherein the shielding sheet perpendicularly extends from one lateral side of the connecting sheet, the limiting sheet perpendicularly extends from the opposite lateral side of the connecting sheet.

9. The magnetron sputtering device of claim 7, wherein the two shielding covers are mounted substantially symmetrically on opposite sides of the magnetron target, and the two shielding sheets are parallelly mounted on opposite sides of the magnetron target.

10. The magnetron sputtering device of claim 7, wherein the vacuum chamber body comprises a door, the limiting sheet of each shielding sheet is secured to an inner surface of the door facing the vacuum chamber.

11. The magnetron sputtering device of claim 10, wherein each shielding sheet is located over the magnetron target and defines a space between the shielding sheet and the magnetron target.

12. The magnetron sputtering device of claim 11, wherein the space formed between the shielding sheet and the magnetron target has a width of about 2.5 cm to about 3.5 cm.

13. The magnetron sputtering device of claim 10, wherein the magnetron target comprises a sputtering region, the sputtering region comprises two parallel areas, each shielding sheet comprises an edge located apart from the connecting sheet, orthographic projection of each edge is located in a corresponding parallel area.

14. The magnetron sputtering device of claim 13, wherein orthographic projection of each edge is located on the centerline of the corresponding parallel area.

15. The magnetron sputtering device of claim 14, wherein the two shielding covers define a space located therebetween.
